(19) United States
(12) Patent Application Publication
(10) Pub. No.: US 2006/0018103 A1
(43) Pub. Date: Jan. 26, 2006

(54) Securing mechanism for swapper of electronic devices

(76) Inventor: Tsou Chia-Lin, Hsinchu (TW)

Correspondence Address: TRANSPACIFIC LAW GROUP, 617 NORTH DELAWARE STREET, SAN MATEO, CA, 94401, US

(21) Appl. No.: 10/897,294

(22) Filed: Jul. 21, 2004

(51) Int. Cl. H05K 5/02

(52) U.S. Cl. 361/756; 361/801; 361/810; 361/727

(57) ABSTRACT

The securing mechanism for swapper of electronic devices of this invention comprises: a casing provided with a plurality of supporting means to support a mother board; at least a group of surrounding ribs to surround outer peripheral of a swapper affixed to said mother board when said mother board is supported on said casing; and a guiding member to guide said swapper into space defined by said group of surrounding rib when said swapper enters into said space defined by said group of surrounding rib. With the securing mechanism of this invention, the swapper is firmly held by the securing mechanism when the mother board and the casing are assembled. Swing movement of the swapper and twist of the mother board will be generated during the plugging and unplugging activity of the mating connector of the swapper.

### FIELD OF THE INVENTION

The present invention relates to securing mechanism for swapper of electronic devices, especially to securing mechanism for connector for electricity or signal line of electronic devices.

### BACKGROUND OF THE INVENTION

In all kinds of electronic devices such as personal computer, facsimile machine, display, printer, digital camera, optical disc drive, card reader, personal digital assistant and other devices that needs to connected with electronic or computer equipments and power supply, a variety of connector is needed, such that the electronic devices may connect or communicate with external system. Nowadays the electronic devices provide the function of “portability”. That is, the electronic devices are not for use in one particular location but are brought to any place where it is connected with power a supply or external systems through connectors attached to or provided in the electronic devices. As a result, such connector shall ensure its normal functionality even after frequent and intensive swapping activities.

The conventional connector for electronic devices or other similar swapper member is provided and secured on the mother board of the electronic device it belongs. The swapper on the one hand is soldered at its connecting pins onto the mother board and is secured to the mother board with securing means such as screw, bolt, solder, jack etc. on the other hand.

With such a securing mechanism, the connecting pins and the securing means secure the swapper firmly to the mother board. However, due to the fact that the mother board is made of material with a certain level of flexibility and that electronic components and circuitry are provided on both sides of the mother board, the swapper tends to swing during the plugging and unplugging activities of a mating connector of the swapper, even if the swapper is firmly secured to the mother board. Such plugging and unplugging activities will loosen the securing means and shorten the lifetime of the swapper.

In addition, the plugging and unplugging activity does not only bring harms to the securing means but also damages the solder by bringing fracture to it. Furthermore, the mother board tends to twist during the plugging and unplugging activity of the swapper, whereby the securing means that secures the electronic components onto the mother board is loosened and the lifetime of the electronic components is shorten as well.

It is thus necessary to provide a novel securing mechanism for swapper of electronic devices that strengthens the endurance of the swapper.

It is also necessary to provide a securing mechanism for swapper of electronic devices to firmly hold the swapper and to avoid swing of the swapper.

It is also necessary to provide a securing mechanism for swapper of electronic devices to avoid distortion of the mother board during the plugging and unplugging activity of the mating connector of the swapper.

### OBJECTIVES OF THE INVENTION

The objective of this invention is to provide a novel securing mechanism for swapper of electronic devices that strengthens the endurance of the swapper.

Another objective of this invention is to provide a securing mechanism for swapper of electronic devices to firmly hold the swapper and to avoid swing of the swapper.

Another objective of this invention is to provide a securing mechanism for swapper of electronic devices to avoid distortion of the mother board during the plugging and unplugging activity of the mating connector of the swapper.

### SUMMARY OF THE INVENTION

According to the present invention, the securing mechanism for swapper of electronic devices of this invention comprises: a casing provided with a plurality of supporting means to support a mother board; at least a group of surrounding ribs to surround outer peripheral of a swapper affixed to said mother board when said mother board is supported on said casing; and a guiding member to guide said swapper into space defined by said group of surrounding rib when said swapper enters into said space defined by said group of surrounding rib. With the securing mechanism of this invention, the swapper is firmly held by the securing mechanism when the mother board and the casing are assembled. Swing movement of the swapper and twist of the mother board will be generated during the plugging and unplugging activity of the mating connector of the swapper.

These and other objectives and advantages of this invention may be clearly illustrated by the detailed description by referring to the drawings.

### BRIEF DESCRIPTION OF THE DRAWINGS

FIG. 1 illustrates the structure of the securing mechanism for swapper of electronic devices of this invention.

FIG. 2 shows its side view.

FIG. 3 shows the cross-sectional view of the securing mechanism for swapper of electronic devices of this invention.

### DETAILED DESCRIPTION OF THE INVENTION

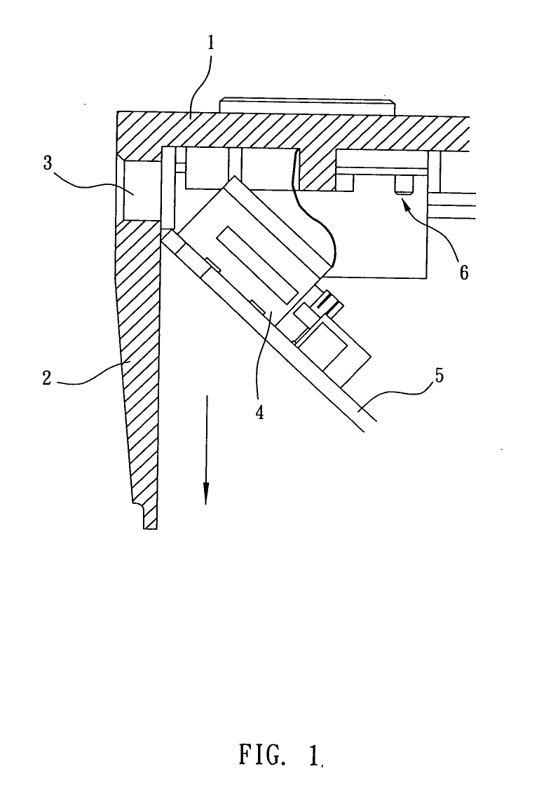

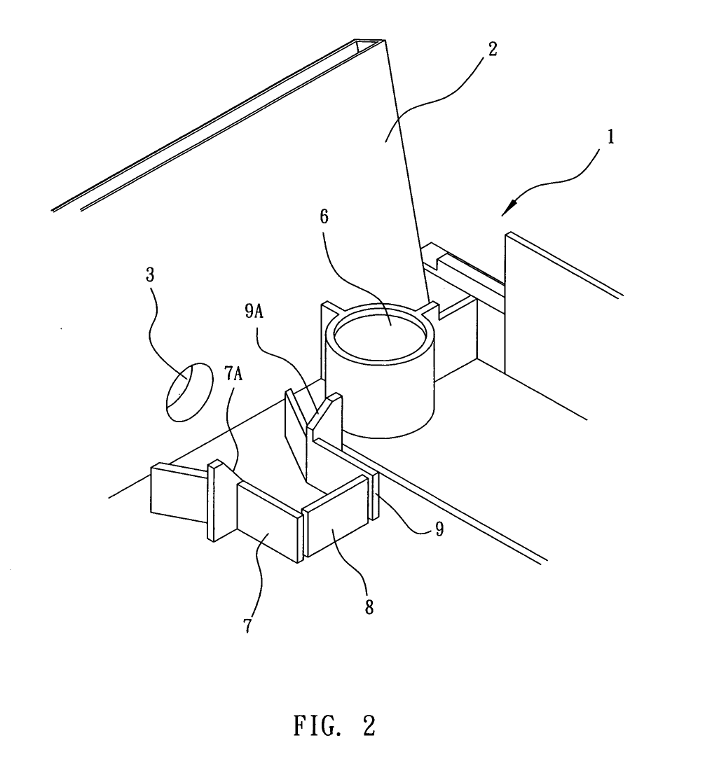

FIG. 1 illustrates the structure of the securing mechanism for swapper of electronic devices of this invention and FIG. 2 shows its side view.

As shown in these figures, the securing mechanism for swapper of electronic devices of this invention is provided in a casing 1. The casing 1 has a side wall 2, on which a hole 3 is formed to allow a plug or a connector for power line or signal line (not shown) to enter into the casing 1. The swapper 4 is affixed to a mother board 5 with connecting pins (not shown) and securing means (not shown). The swapper as shown in these figures is a jack for power plug. Of course, other types of swapper, such as connectors and converters with all types of communication interface are applicable to this invention.

The supporting means 6 is provided in the casing 1 to support the mother board 5 when it is assembled with the casing 1. The supporting means 6 as shown in these figures is screw. However, other supporting means such as bolt, solder, adhesives, hinge etc. are also applicable. The number of the securing means 6 is not limited in any aspect, as long as the mother board 5 is firmly supported on the casing 1. Shown in these figure as also a plurality of ribs 7, 8, 9 surrounding the space corresponding to that occupied by the swapper 4 on the mother board 5. The space defined by the surrounding ribs 7, 8, 9 is preferably of the same size and shape of the swapper 4, such that the ribs 7, 8, 9 form a group of surrounding ribs to hold the swapper 4 when it enters into the space, whereby no swing movement is generated during the plugging and unplugging activities of the mating connector of the swapper 4. On the surrounding ribs 7 and 9, at the positions adjacent to the hole 3, provided is a V shape layout. The V shape layout functions as guiding member to guide the swapper 4 into the space defined by the surrounding ribs 7, 8, 9 when the mother board 5 is assembled to the casing 1, without any interference.

In addition, on the upper surface of the ribs 7 and 9 round recessions 7a, 9a are formed to prevent interference of the swapper 4 by the ribs 7 and 9, when the mother board 5 is assembled to the casing 1. Such interference preventing mechanism may be a simple recession or the like.

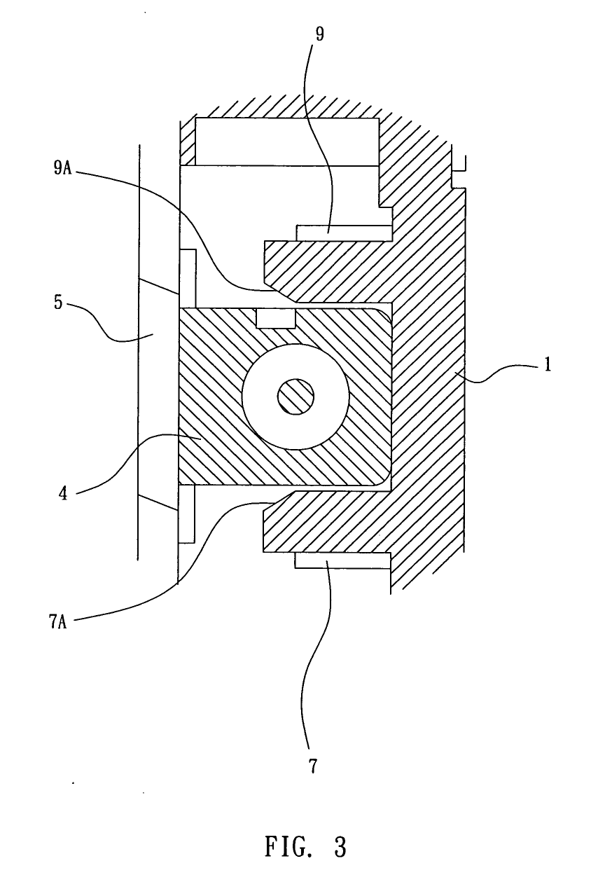

The securing mechanism for swapper of electronic devices as described above may firmly hold the swapper when the mother board 5 is assembled with the casing 1, whereby no swing movement of the swapper 5 or twisting movement of the mother board 5 is generated when the mating connector (not shown) of the swapper 4 is plugged into or unplugged from the swapper 4. FIG. 3 shows the cross-sectional view of a part of the securing mechanism for swapper of electronic devices of this invention. As shown in this figure, the securing mechanism for swapper of electronic devices of this invention firmly holds the swapper in position to prevent any damage to the swapper and the motherboard.

As the present invention has been shown and described with reference to preferred embodiments thereof, those skilled in the art will recognize that the above and other changes may be made therein without departing form the spirit and scope of the invention.

What is claimed is:

1. Securing mechanism for swapper of electronic device, comprising securing mechanism provided in casing of said electronic device, which securing mechanism comprises:
a plurality of supporting means to support a mother board;
at least one group of surrounding ribs to surround outer peripheral of a swapper provided on said mother board, when said mother board is affixed to said casing; and
a guiding member to guide said swapper to enter into space defined by said surrounding ribs when said mother board is affixed to said casing.

2. The securing mechanism for swapper of electronic device according to claim 1, wherein said guiding member is a V shape formed by said surrounding ribs.

3. The securing mechanism for swapper of electronic device according to claim 1, wherein said guiding member is a recession formed on at least one of said surrounding ribs.

4. The securing mechanism for swapper of electronic device according to claim 1, wherein said guiding member is a round recession formed on at least one of said surrounding ribs.
